(19) United States
(12) Patent Application Publication
(10) Pub. No.: US 2016/0282400 A1
(43) Pub. Date: Sep. 29, 2016

(54) EQUIPMENT FAILURE PREDICTION SYSTEM, EQUIPMENT FAILURE PREDICTION DEVICE AND EQUIPMENT FAILURE PREDICTION METHOD

(71) Applicant: Hitachi Ltd., Tokyo (JP)

(72) Inventors: Yoshiki YUMBE, Tokyo (JP); Misa MIYAKOSHI, Tokyo (JP); Hitoshi OKABE, Tokyo (JP); Isao KAWAKAMI, Tokyo (JP)

(21) Appl. No.: 15/080,758

(22) Filed: Mar. 25, 2016

(30) Foreign Application Priority Data
Mar. 25, 2015 (JP) 2015-063235

(51) Int. Cl. G01R 31/02

(52) U.S. Cl. CPC G01R 31/027

(57) ABSTRACT

An equipment failure prediction system includes an equipment failure prediction device and smart meters which are all connectable to a network, and a transformer that provides information to the smart meters. The smart meters transmit quantitative data to the equipment failure prediction device through the network, the quantitative data obtained by quantifying the information provided by the transformer. The equipment failure prediction device accumulates the transmitted quantitative data in a database and predicts occurrence of failure in the transformer by using a statistic calculated from the quantitative data accumulated in the database.

### BACKGROUND OF THE INVENTION

1. Field of the Invention

The present invention relates to an equipment failure prediction system, an equipment failure prediction device and an equipment failure prediction method that are capable of predicting occurrence of failure in inspection target equipment.

2. Description of the Related Art

Japanese Patent Application Publication No. 2010-097392 discloses an equipment degradation prediction system and an equipment degradation prediction method capable of predicting degradation of equipment based on qualitative data indicating the state of the equipment and quantitative data provided from the equipment.

Degradation of power distribution equipment such as a transformer, for example, varies depending on not only external environment including equipment specifications such as the materials of instruments in the equipment and characteristics of a region where the equipment is installed, but also the internal state such as load information on current, voltage, electrical power, and the like inside the equipment. The method disclosed in Japanese Patent Application Publication No. 2010-097392 does not use information on the internal state, and thus cannot accurately predict the degradation in accordance with the internal state.

The present invention has been made in view of the problem described above, and an object of the present invention is to provide an equipment failure prediction system, an equipment failure prediction device and an equipment failure prediction method that are capable of accurately predict occurrence of failure in inspection target equipment.

### SUMMARY OF THE INVENTION

The present invention has been made to solve the above problem and makes it an object thereof to provide an equipment failure prediction system including: an equipment failure prediction device connectable to a network; a data storage device storing a database therein; and a plurality of terminal devices connectable to the network. Each of the terminal devices transmits quantitative data to the equipment failure prediction device through the network, the quantitative data obtained by quantifying information provided by inspection target equipment, and the equipment failure prediction device accumulates the transmitted quantitative data in the database, and predicts occurrence of failure at the inspection target equipment by using a statistic calculated from the quantitative data accumulated in the database. The present invention also provides the equipment failure prediction device provided to the equipment failure prediction system, and an equipment failure prediction method.

According to the present invention, it is possible to provide an equipment failure prediction system, an equipment failure prediction device and an equipment failure prediction method that are capable of accurately predicting occurrence of failure in inspection target equipment. This allows determination of an inspection target so as to improve the efficiency thereof when the inspection target equipment is to be inspected.

### BRIEF DESCRIPTION OF THE DRAWINGS

FIG. 1 illustrates the entire configuration of an equipment failure prediction system according to the present embodiment.

FIG. 2 is a block diagram of the configuration of a database.

FIGS. 3A, 3B, and 3C each illustrate an exemplary configuration of data included in equipment data: FIG. 3A illustrates equipment correspondence data, FIG. 3B illustrates span data, and FIG. 3C illustrates instrument information data.

FIGS. 4A and 4B each illustrate an exemplary configuration of data included in measured data: FIG. 4A illustrates smart meter data, and FIG. 4B illustrates instrument-associated data.

FIG. 5 illustrates an exemplary configuration of measured statistic data.

FIG. 6 illustrates an exemplary configuration of inspection history data.

FIG. 7 illustrates an exemplary configuration of installation environment data.

FIG. 8 is a flowchart of a procedure by which an equipment failure prediction system predicts failure of equipment.

FIG. 9 illustrates a prediction data table.

FIG. 10 illustrates an example of categorizing measured statistic data.

FIGS. 11A and 11B are each a pattern diagram illustrating an outline of applying mathematical quantification theory class II to the present embodiment: FIG. 11A illustrates a prediction data table, and FIG. 11B is a schematic diagram illustrating distribution of data groups.

FIG. 12 illustrates a determination formula.

FIG. 13A illustrates sample data used to predict an inspection result, and FIG. 13B illustrates a result of determination by the determination formula.

### DETAILED DESCRIPTION OF THE EMBODIMENTS

Embodiments of the present invention will be hereinafter described in detail with reference to the accompanying drawings.

### Embodiment

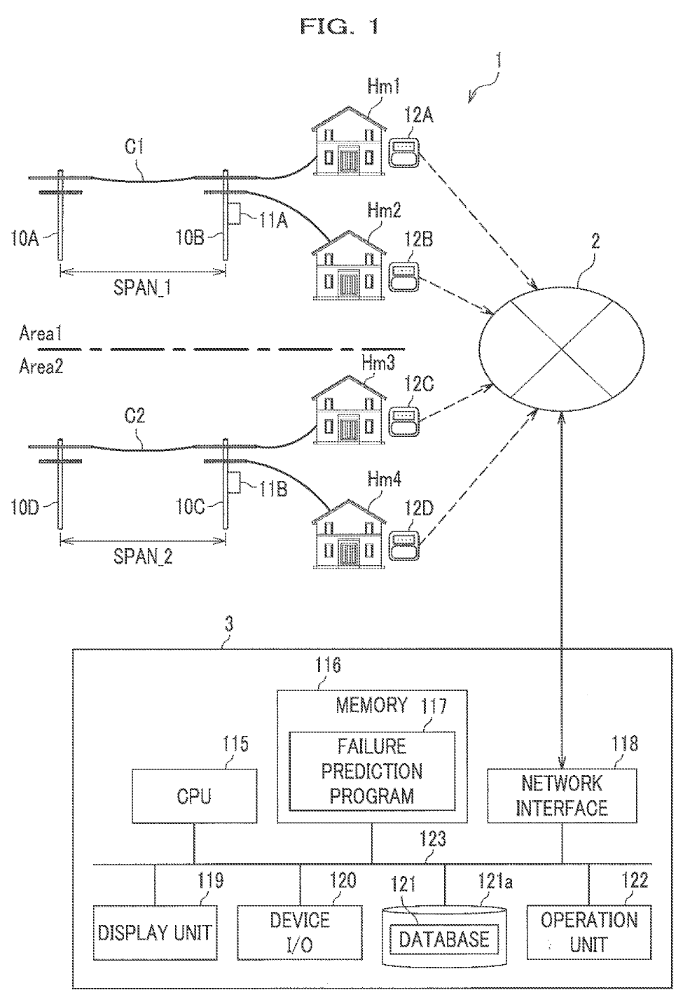

FIG. 1 illustrates the entire configuration of an equipment failure prediction system according to the present embodiment.

An equipment failure prediction system 1 according to the embodiment of the present invention predicts an inspection result (occurrence of failure) of equipment (in the present embodiment, a first transformer 11A and a second transformer 11B) by using qualitative data and quantitative data in combination. The qualitative data includes information (equipment data) indicating the state of the equipment, information (installation environment data) on environment in which the equipment is installed, and information (inspection history data) obtained through an inspection of the equipment. The quantitative data includes the amount of electrical power read from, for example, a smart meter (a first smart meter 12A, a second smart meter 12B, a third smart meter 12C, or a fourth smart meter 12D) as a terminal device installed at a house (a first house Hm1, a second house Hm2, a third house Hm3, or a fourth house Hm4).

The equipment failure prediction system 1 according to the present embodiment is provided to electrical power distribution equipment, and configured to predict occurrence of failure in a transformer (the first transformer 11A or the second transformer 11B) mounted on a power pole (a first power pole 10A, a second power pole 10B, a third power pole 10C, or a fourth power pole 10D). Thus, in the present embodiment, the first transformer 11A and the second transformer 11B are each an inspection target equipment of which inspection result (occurrence of failure) is predicted by the equipment failure prediction system 1.

As illustrated in FIG. 1, the equipment failure prediction system 1 according to the present embodiment includes an equipment failure prediction device 3 connected to a network 2.

The network 2 may be a general-purpose network such as the Internet network, or may be a dedicated network (such as a wide area network (WAN)) for the equipment failure prediction system 1.

The equipment failure prediction system 1 manages the four power poles (the first power pole 10A, the second power pole 10B, the third power pole 10C, and the fourth power pole 10D) provided as the electrical power distribution equipment. The first power pole 10A and the second power pole 10B support a first electric wire C1, and the fourth power pole 10D and the third power pole 10C support a second electric wire C2. In the present embodiment, “SPAN_1” is a span ID for specifying a separation (first span) between the first power pole 10A and the second power pole 10B, and “SPAN_2” is a span ID for specifying a separation (second span) between the third power pole 10C and the fourth power pole 10D.

FIG. 1 illustrates an example in which the equipment failure prediction system manages the electrical power distribution equipment provided across two areas (Area 1 and Area 2).

The two areas are classified depending on their environments affecting the electrical power distribution equipment, such as whether salt damage is likely to occur and whether to have heavy snowfall. The present embodiment describes an example in which the classification is made depending on whether salt damage is likely to occur. Area 2 is an area such as a coast in which salt damage is likely to occur, and Area 1 is an area such as an inland in which salt damage is unlikely to occur.

The second power pole 10B is provided with the first transformer 11A. The first transformer 11A transforms the voltage of the first electric wire C1 to a voltage to be distributed to houses (the first house Hm1 and the second house Hm2). Electrical power transformed by the first transformer 11A is distributed to the two houses (the first house Hm1 and the second house Hm2) from the second power pole 10B.

The third power pole 10C is provided with the second transformer 11B. The second transformer 11B transforms the voltage of the second electric wire C2 to a voltage to be distributed to houses (the third house Hm3 and the fourth house Hm4). Electrical power transformed by the second transformer 11B is distributed to the two houses (the third house Hm3 and the fourth house Hm4) from the third power pole 10C.

The number of houses to which power is distributed from the first transformer 11A or the second transformer 11B is not limited. The first transformer 11A or the second transformer 11B may distribute power to three houses or more.

The smart meters (the first smart meter 12A, the second smart meter 12B, the third smart meter 12C, the fourth smart meter 12D) are installed at the respective four houses (the first house Hm1, the second house Hm2, the third house Hm3, and the fourth house Hm4). Each smart meter is capable of measuring the amount of electrical power used at the corresponding house. For example, the first smart meter 12A is capable of measuring the amount of electrical power used at the first house Hm1.

The first smart meter 12A to the fourth smart meter 12D are capable of measuring the voltages (voltage values) and currents (current values) of electrical power distributed to the first house Hm1 to the fourth house Hm4, respectively. For example, the first smart meter 12A is capable of measuring the voltage and the current of the electrical power distributed to the first house Hm1.

As described above, the smart meters (the first smart meter 12A to the fourth smart meter 12D) are capable of measuring the amounts of electrical power, voltages, and currents of electrical power distributed from the transformers (the first transformer 11A and the second transformer 11B). Thus, in the present embodiment, the electrical power distributed from each transformer is information provided to the corresponding smart meters by the transformer. The smart meter is configured to quantify the information (electrical power) provided by the transformer into the amounts of electrical power, a voltage, and a current, which are treated as quantitative data.

Each smart meter (the first smart meter 12A to the fourth smart meter 12D) periodically transmits measured amounts of electrical power, voltage, and current (quantitative data) as actual measured values to the equipment failure prediction device 3 through the network 2. For this reason, the smart meter is preferably provided with an interface connectable to the network 2. The smart meter may be connected to the network 2 in a wired or wireless manner.

In the present embodiment, the first smart meter 12A to the fourth smart meter 12D are terminal devices connected to the network 2 and further to the equipment failure prediction device 3 through the network 2.

The electrical power distribution equipment (the first power pole 10A to the fourth power pole 10D, the first transformer 11A, and the second transformer 11B, for example) illustrated in FIG. 1 is an example for describing the present embodiment, and is not limited to the configuration in FIG. 1.

The equipment failure prediction device 3 configured to control the equipment failure prediction system 1 according to the present embodiment includes a central processing unit (CPU) 115, a memory 116, a network interface 118, a display unit 119, a device I/O 120, a database 121, and an operation unit 122. The database 121 is stored (accumulated) in a data storage device 121a. The CPU 115, the memory 116, the network interface 118, the display unit 119, the device I/O 120, the data storage device 121a, and the operation unit 122 are connected to each other through a data bus 123, and configured to transmit and receive data with each other.

The memory 116 is a non-volatile storage unit storing therein a failure prediction program 117. The CPU 115 is a control unit that executes the failure prediction program 117 to control the equipment failure prediction device 3. The equipment failure prediction system 1 is controlled by the equipment failure prediction device 3 (CPU 115). The network interface 118 is an interface unit for connecting the equipment failure prediction device 3 to the network 2. The database 121 include, for example, information on the equipment (the first power pole 10A to the fourth power pole 10D, the first transformer 11A, and the second transformer 11B, for example) (for example, information indicating the state of the equipment) managed by the equipment failure prediction system 1, the inspection history data, and the actual measured values transmitted from the smart meters (the first smart meter 12A to the fourth smart meter 12D). The database 121 is stored (accumulated) in the predetermined data storage device 121a. Examples of the operation unit 122 include a keyboard and a mouse operated by, for example, an inspector. The device I/O 120 is a connection terminal connecting external instruments such as a universal serial bus (USB) memory and a hard disk.

The equipment failure prediction system 1 according to the present embodiment is controlled by the equipment failure prediction device 3 configured in this manner.

Each smart meter (the first smart meter 12A to the fourth smart meter 12D) installed at the corresponding house (the first house Hm1 to the fourth house Hm4) measures the amount of electrical power used at the house and the voltage and current of electrical power distributed to the house, and periodically transmits the actual measured values to the equipment failure prediction device 3. The smart meter according to the present embodiment transmits the actual measured values to the equipment failure prediction device 3 through the network 2. The equipment failure prediction device 3 stores actual measured values transmitted from each smart meter in the data storage device 121a and accumulates the actual measured values in the database 121.

The CPU 115 executes the failure prediction program 117 to predict occurrence of failure in the equipment (in the present embodiment, the first transformer 11A and the second transformer 11B). In the prediction, the CPU 115 uses qualitative data (qualitative data D1 to be described later) and quantitative data (quantitative data D2 to be described later) in combination, which are accumulated in the database 121. The qualitative data includes information indicating the state of the equipment and an inspection history. The quantitative data includes actual measured values transmitted from the smart meters (the first smart meter 12A to the fourth smart meter 12D). Processing performed by the CPU 115 executing the failure prediction program 117 will be described in detail later.

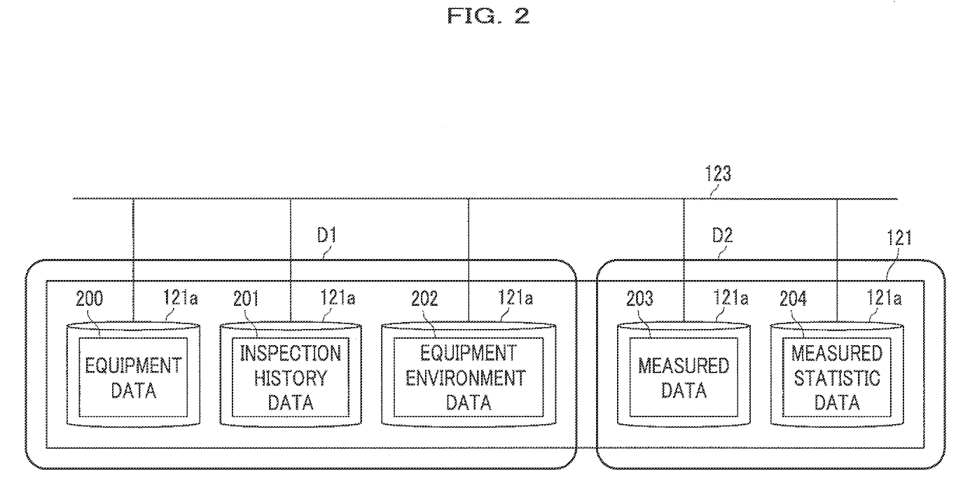

The following describes the configuration of the database 121 provided to the equipment failure prediction device 3 illustrated in FIG. 1 with reference to FIGS. 2 to 6.

FIG. 2 is a block diagram of the configuration of the database.

As illustrated in FIG. 2, the database 121 includes equipment data 200, inspection history data 201, installation environment data 202, measured data 203, and measured statistic data 204.

The equipment data 200 includes information on equipment the failure of which is to be predicted, and in the present embodiment, includes information indicating the states of the first transformer 11A and the second transformer 11B illustrated in FIG. 1.

The inspection history data 201 includes information acquired through an inspection of the first transformer 11A and the second transformer 11B by the inspector.

The installation environment data 202 includes information on environment in which the first transformer 11A and the second transformer 11B are installed. In the present embodiment, the installation environment data 202 includes information on environment of Area 1 (refer to FIG. 1) in which the first transformer 11A is installed, and information on environment of Area 2 (refer to FIG. 1) in which the second transformer 11B is installed.

The measured data 203 includes actual measured values transmitted to the equipment failure prediction device 3 by each smart meter (the first smart meter 12A to the fourth smart meter 12D) in FIG. 1 measuring the amount of electrical power used at the corresponding house (the first house Hm1 to the fourth house Hm4). The actual measured values transmitted from the smart meter include the voltage and current of electrical power distributed to the house.

The measured statistic data 204 includes a statistic calculated from the measured data 203. The statistic included in the measured statistic data 204 is calculated from the measured data 203 by the CPU 115 (refer to FIG. 1) of the equipment failure prediction device 3.

Among the pieces of data included in the database 121, the equipment data 200, the inspection history data 201, and the installation environment data 202 are qualitative data referred to as the qualitative data D1 in the present embodiment. The measured data 203 and the measured statistic data 204 are quantitative data referred to as the quantitative data D2 in the present embodiment. Each piece of data will be described in detail later.

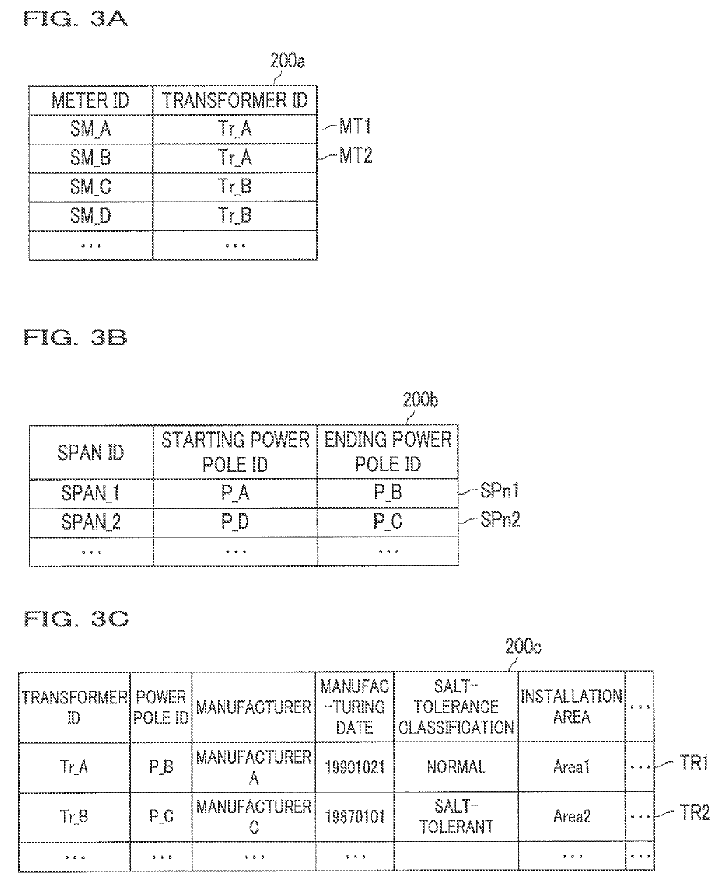

FIGS. 3A, 3B, and 3C each illustrate an exemplary configuration of data included in the equipment data: FIG. 3A illustrates equipment correspondence data, FIG. 3B illustrates span data, and FIG. 3C illustrates instrument information data.

The equipment data 200 illustrated in FIG. 2 includes equipment correspondence data 200a (refer to FIG. 3A), span data 200b (refer to FIG. 3B), and instrument information data 200c (refer to FIG. 3C).

As illustrated in FIG. 3A, the equipment correspondence data 200a includes the IDs (meter IDs) of the smart meters and the IDs (transformer IDs) of the corresponding transformers. The equipment correspondence data 200a associates each house with a transformer that distributes electrical power to the house.

In the present embodiment, “SM_A” is the meter ID of the first smart meter 12A (refer to FIG. 1), “SM_B” is the meter ID of the second smart meter 12B (refer to FIG. 1), “SM_C” is the meter ID of the third smart meter 12C (refer to FIG. 1), and “SM_D” is the meter ID of the fourth smart meter 12D (refer to FIG. 1).

“Tr_A” is the transformer ID of the first transformer 11A (refer to FIG. 1), and “Tr_B” is the transformer ID of the second transformer 11B (refer to FIG. 1).

As illustrated in FIG. 1, one smart meter (the first smart meter 12A to the fourth smart meter 12D) is installed at each of the first house Hm1 to the fourth house Hm4, and provided with a unique meter ID (SM_A to SM_D). In this manner, the equipment correspondence data 200a associates each house (the first house Hm1 to the fourth house Hm4) with a transformer (the first transformer 11A and the second transformer 11B) that distributes electrical power to the house.

“MT1” and “MT2” in FIG. 3A denote exemplary aggregations of data included in the equipment correspondence data 200a (hereinafter, such an aggregation of data will be referred to as a data group). In FIG. 3A, the data group “MT1” corresponds to the first smart meter 12A (meter ID: SM_A), indicating that the transformer corresponding to the first smart meter 12A is the first transformer 11A (transformer ID: Tr_A). The data group “MT2” corresponds to the second smart meter 12B (meter ID: SM_B), indicating that the transformer corresponding to the second smart meter 12B is the first transformer 11A (transformer ID: Tr_A).

As illustrated in FIG. 3B, the span data 200b includes a span ID indicating a separation (span) between power poles, and data on the power poles (the first power pole 10A to the fourth power pole 10D) corresponding to the span ID.

In the present embodiment, each power pole (the first power pole 10A to the fourth power pole 10D) is provided with a power pole ID. “P_A” is the power pole ID of the first power pole 10A, “P_B” is the power pole ID of the second power pole 10B, “P_C” is the power pole ID of the third power pole 10C, and “P_D” is the power pole ID of the fourth power pole 10D.

The span data 200b sets the power pole ID of a starting power pole and the power pole ID of an ending power pole, which correspond to a span ID.

For example, as illustrated in FIG. 1, when the first span (span ID: SPAN_1) indicates a separation between the first power pole 10A (power pole ID: P_A) and the second power pole 10B (power pole ID: P_B), the ending power pole is the second power pole 10B provided with a transformer (the first transformer 11A), and the starting power pole is the first power pole 10A not provided with a transformer. In other words, the ending power pole is the downstream side in power distribution of electrical power.

“SPn1” and “SPn2” in FIG. 3B denote exemplary data groups included in the span data 200b. For example, the data group “SPn1” corresponds to the first span (span ID: SPAN_1), indicating that the starting power pole of the first span is the first power pole 10A (power pole ID: P_A) and the ending power pole thereof is the second power pole 10B (power pole ID: P_B). The data group “SPn2” corresponds to the second span (span ID: SPAN_2), indicating that the starting power pole of the second span is the fourth power pole 10D (power pole ID: P_D) and the ending power pole thereof is the third power pole 10C (power pole ID: P_C).

The span data 200b clearly indicates which power poles are connected to each other.

As illustrated in FIG. 3C, the instrument information data 200c includes information on the first transformer 11A (refer to FIG. 1) and the second transformer 11B (refer to FIG. 1). For example, a data group “TR1” corresponds to the first transformer 11A (transformer ID: Tr_A), indicating a power pole (the second power pole 10B) to which the first transformer 11A is attached, and the manufacturer (manufacturer A), manufacturing date (Oct. 21, 1990), salt-tolerance classification (normal), and installation area (Area 1) of the first transformer 11A. A data group “TR2” corresponds to the second transformer 11B (transformer ID: Tr_B), indicating a power pole (the third power pole 10C) to which the second transformer 11B is attached, and the manufacturer (manufacturer C), manufacturing date (Jan. 1, 1987), salt-tolerance classification (salt tolerance), and installation area (Area 2) of the second transformer 11B.

The salt-tolerance classification in the instrument information data 200c is information indicating durability to salt damage. The salt-tolerance classification indicates, for example, that a transformer classified as “salt tolerance” has a structure durable to salt damage.

The instrument information data 200c illustrated in FIG. 3C relates to equipment (such as a transformer and a power pole) as the target of an inspection of the electrical power distribution equipment, and is mainly data needed for the inspection. Thus, the instrument information data 200c is not limited to items listed in FIG. 3C, and may include an item needed at an inspection as appropriate.

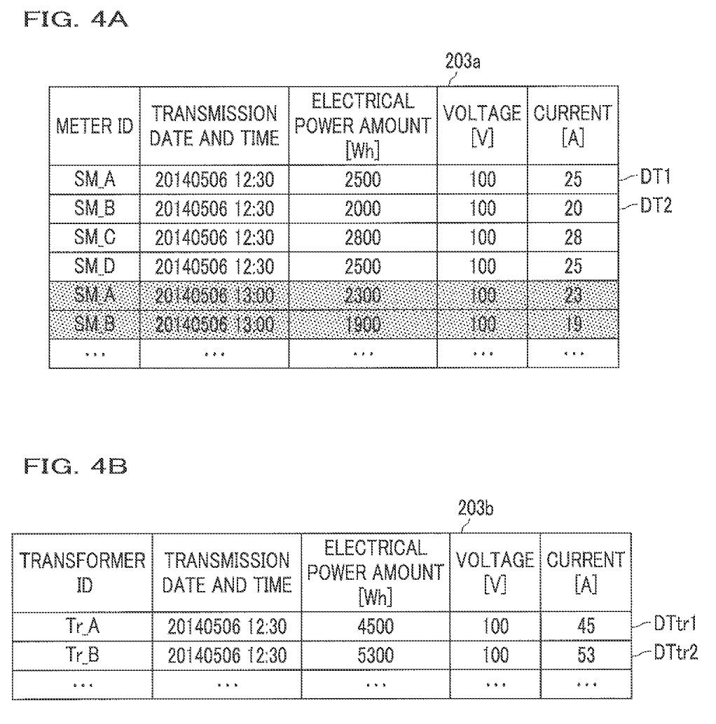

FIGS. 4A and 4B each illustrate an exemplary configuration of data included in measured data: FIG. 4A illustrates smart meter data, and FIG. 4B illustrates instrument-associated data.

The measured data 203 illustrated in FIG. 2 includes smart meter data 203a (refer to FIG. 4A) and instrument-associated data 203b (refer to FIG. 4B).

As illustrated in FIG. 4A, the smart meter data 203a includes a meter ID, a transmission date and time, the amount of electrical power, a voltage (voltage value), and a current (current value).

The smart meter data 203a is data (the quantitative data D2) including actual measured values transmitted from the first smart meter 12A to the fourth smart meter 12D (refer to FIG. 1). The transmission date and time may be date and time at which the equipment failure prediction device 3 (refer to FIG. 1) received the actual measured values transmitted from each smart meter, or date and time at which the smart meter transmitted the actual measured values. When the date and time at which the smart meter transmitted the actual measured values is used, this date and time is preferably included in the actual measured values.

A data group “DT1” illustrated in FIG. 4A includes actual measured values transmitted from the first smart meter 12A (meter ID: SM_A), i.e. the transmission date and time (12:30 on May 6, 2014), the amount of electrical power (2500 Wh), the voltage (100 V), and the current (25 A). A data group “DT2” includes actual measured values transmitted from the second smart meter 12B (meter ID: SM_B), i.e. the transmission date and time (12:30 on May 6, 2014), the amount of electrical power (2000 Wh), the voltage (100 V), and the current (20 A).

The present embodiment describes an example in which the first smart meter 12A to the fourth smart meter 12D (refer to FIG. 1) each transmit actual measured values at an interval of 30 minutes. In this case, the actual measured values such as the amount of electrical power, the voltage, and the current may be average values in the last 30 minutes, or maximum values (or minimum values) in the last 30 minutes. In other words, each smart meter is configured to transmit the average values or maximum values (minimum values) of the amount of electrical power, the voltage, and the current to the equipment failure prediction device 3 (refer to FIG. 1) for each 30 minutes. The interval at which the smart meter transmits the actual measured values is not limited to 30 minutes.

The instrument-associated data 203b illustrated in FIG. 4B associates the smart meter data 203a with the first transformer 11A (refer to FIG. 1) and the second transformer 11B (refer to FIG. 1).

A data group “DTtr1” illustrated in FIG. 4B includes data on the first transformer 11A (transformer ID: Tr_A) illustrated in FIG. 1, indicating the transmission date and time (12:30 on May 6, 2014) at which actual measured values were transmitted, the amount of electrical power (4500 Wh), the voltage (100 V), and the current (45 A). A data group “DTtr2” illustrated in FIG. 4B includes data on the second transformer 11B (transformer ID: Tr_B) illustrated in FIG. 1, indicating the transmission date and time (12:30 on May 6, 2014) at which actual measured values were transmitted, the amount of electrical power (5300 Wh), the voltage (100V), and the current (53 A).

As illustrated in FIG. 1, the first power pole 10A and the second power pole 10B are arranged at an interval of the first span (span ID: SPAN_1) to support the first electric wire C1. The first transformer 11A is provided to the second power pole 10B, and distributes electrical power to the first house Hm1 and the second house Hm2. The first smart meter 12A is installed at the first house Hm1, and the second smart meter 12B is installed at the second house Hm2.

The fourth power pole 10D and the third power pole 10C are arranged at an interval of the second span (span ID: SPAN_2) to support the second electric wire C2. The second transformer 11B is provided to the third power pole 10C, and distributes electrical power to the third house Hm3 and the fourth house Hm4. The third smart meter 12C is installed at the third house Hm3, and the fourth smart meter 12D is installed at the fourth house Hm4.

The equipment correspondence data 200a (refer to FIG. 3A) and the span data 200b (refer to FIG. 3B) included in the equipment data 200 (refer to FIG. 2) associates the arrangement of the pieces of equipment illustrated in FIG. 1 based on the meter ID, the transformer ID, the span ID, and the power pole ID.

As indicated in the equipment correspondence data 200a (refer to FIG. 3A), the first transformer 11A (transformer ID: Tr_A) is connected to the first smart meter 12A (meter ID: SM_A) and the second smart meter 12B (meter ID: SM_B). The second transformer 11B (transformer ID: Tr_B) is connected to the third smart meter 12C (meter ID: SM_C) and the fourth smart meter 12D (meter ID: SM_D).

Accordingly, actual measured values related to the first transformer 11A are expressed by the following equations 1A to 1C.

Ptr(Tr_A)=Pmt(SM_A)+Pmt(SM_B) (1A)

Vtr(Tr_A)=Vmt(SM_A)=Vmt(SM_B) (1B)

Itr(Tr_A)=Imt(SM_A)+Imt(SM_B) (1C)

Similarly, actual measured values related to the second transformer 11B are expressed by the following equations 2A to 2C.

Ptr(Tr_B)=Pmt(SM_C)+Pmt(SM_D) (2A)

Vtr(Tr_B)=Vmt(SM_C)=Vmt(SM_D) (2B)

Itr(Tr_B)=Imt(SM_C)+Imt(SM_D) (2C)

Ptr in Equations 1A and 2A represents the amount of electrical power of the transformer corresponding to a transformer ID in the parentheses. Specifically, Ptr(Tr_A) in Equation 1A represents the amount of electrical power of the first transformer 11A, and Ptr(Tr_B) in Equation 2A represents the amount of electrical power of the second transformer 11B.

Pmt in Equations 1A and 2A represents the amount of electrical power measured by the smart meter corresponding to a meter ID in the parentheses. Specifically, Pmt (SM_A) and Pmt (SM_B) in Equation 1A represent the amounts of electrical power measured by the first smart meter 12A and the second smart meter 12B, respectively. Similarly, Pmt(SM_C) and Pmt(SM_D) in Equation 2A represent the amounts of electrical power measured by the third smart meter 12C and the fourth smart meter 12D, respectively.

Vtr in Equations 1B and 2B represents the voltage of electrical power fed by the transformer corresponding to a transformer ID in the parentheses. Specifically, Vtr (Tr_A) in Equation 1B represents the voltage of the first transformer 11A, and Vtr (Tr_B) in Equation 2B represents the voltage of the second transformer 11B.

Vmt in Equations 1B and 2B represents a voltage measured by the smart meter corresponding to a meter ID in the parentheses. Specifically, Vmt(SM_A) and Vmt(SM_B) in Equation 1B represent voltages measured by the first smart meter 12A and the second smart meter 12B, respectively. Similarly, Vmt(SM_C) and Vmt(SM_D) in Equation 2B represent voltages measured by the third smart meter 12C and the fourth smart meter 12D, respectively.

Itr in Equations 1C and 2C represents the current of electrical power fed by the transformer corresponding to a transformer ID in the parentheses. Specifically, Itr (Tr_A) in Equation 1C represents the current of the first transformer 11A, and Itr (Tr_B) in Equation 2C represents the current of the second transformer 11B.

Imt in Equations 1C and 2C represents a current measured by the smart meter corresponding to a meter ID in the parentheses. Specifically, Imt(SM_A) and Imt(SM_B) in Equation 1C represent currents measured by the first smart meter 12A and the second smart meter 12B, respectively. Similarly, Imt(SM_C) and Imt(SM_D) in Equation 2C represent currents measured by the third smart meter 12C and the fourth smart meter 12D, respectively.

As described above, the actual measured values corresponding to the first transformer 11A can be calculated from actual measured values by the first smart meter 12A and the second smart meter 12B based on Equations 1A to 1C. The actual measured values corresponding to the second transformer 11B can be calculated from actual measured values by the third smart meter 12C and the fourth smart meter 12D based on Equations 2A to 2C.

Then, in the smart meter data 203a, “Pmt” in Equation 1A or 2A corresponding to meter IDs is set as the amount of electrical power, “Vmt” in Equation 1B or 2B corresponding to the meter IDs is set as the voltage, and “Imt” in Equation 1C or 2C corresponding to the meter IDs is set as the current.

In the instrument-associated data 203b, “Ptr” corresponding to a transformer ID and calculated by Equations 1A and 2A is set as the amount of electrical power, “Vtr” corresponding to a transformer ID and calculated by Equations 1B and 2B is set as the voltage, and “Itr” corresponding to a transformer ID and calculated by Equations 1C and 2C is set as the current.

As described above, the equipment failure prediction device 3 (refer to FIG. 1) aggregates actual measured values (the smart meter data 203a) transmitted from each smart meter (the first smart meter 12A to the fourth smart meter 12D), and generates the instrument-associated data 203b by associating the actual measured values with the corresponding transformer (the first transformer 11A and the second transformer 11B).

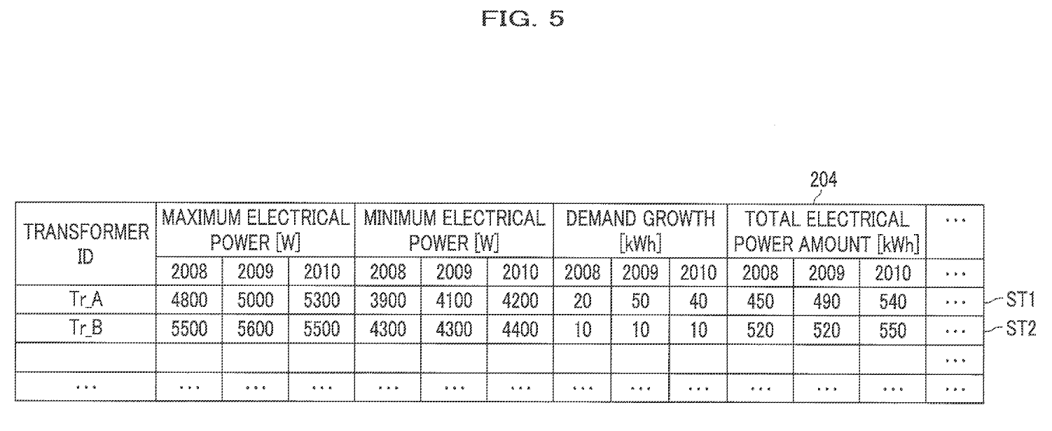

FIG. 5 illustrates an exemplary configuration of the measured statistic data.

As illustrated in FIG. 5, the measured statistic data 204 includes a transformer ID, a maximum electrical power, a minimum electrical power, a demand growth, and the total amount of electrical power. In the present embodiment, the maximum and minimum electrical powers, the demand growth, and the total amount of electrical power included in the measured statistic data 204 are statistics of every year (fiscal year). The measured statistic data 204 is not limited statistics of every year, and may be statistics of every six months or every season. The measured statistic data 204 may include the average amount of electrical power in a predetermined duration (for example, one year) in place of the maximum electrical power and the minimum electrical power.

A data group “ST1” in the measured statistic data 204 illustrated in FIG. 5 includes a statistic corresponding to the first transformer 11A (transformer ID: Tr_A), and a data group “ST2” includes a statistic corresponding to the second transformer 11B (transformer ID: Tr_B).

The maximum electrical power and the minimum electrical power are the maximum value and minimum value of electrical power distributed from each transformer in a duration of interest. The demand growth represents a difference in the total amount of electrical power between in a duration of interest and in the previous duration. For example, the demand growth in 2008 represents a change in the total amount of electrical power from the previous year (2007) to 2008. The total amount of electrical power is the sum of the amounts of electrical power in a duration of interest.

As described above, the equipment failure prediction device illustrated in FIG. 1 calculates statistics (the maximum electrical power, the minimum electrical power, the demand growth, and the total amount of electrical power, for example) from actual measured values (the instrument-associated data 203b illustrated in FIG. 4B) associated with the corresponding transformers (the first transformer 11A and the second transformer 11B) so as to generate the measured statistic data 204 illustrated in FIG. 5.

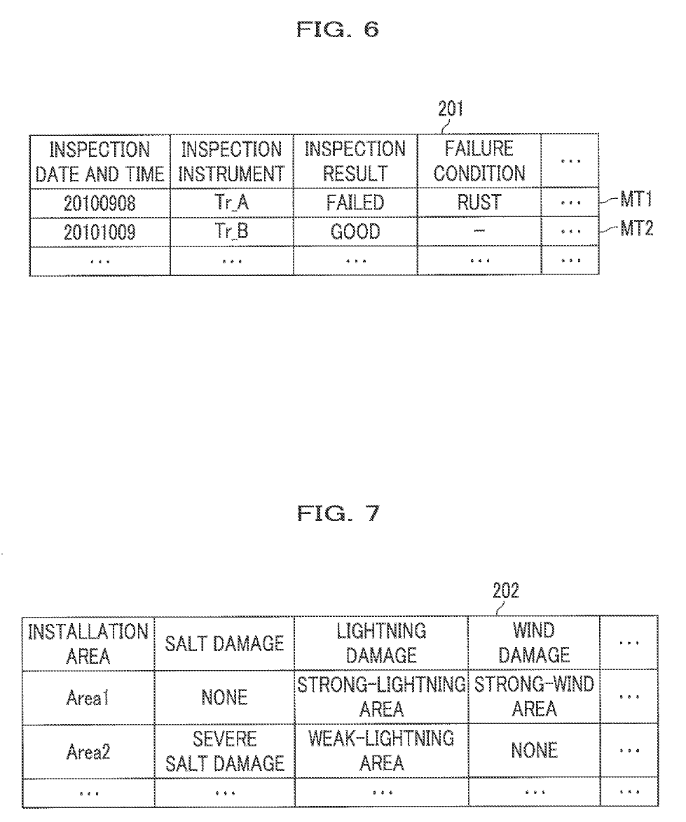

FIG. 6 illustrates an exemplary configuration of the inspection history data.

As illustrated in FIG. 6, the inspection history data 201 according to the present embodiment includes an inspection date and time, an inspection instrument, an inspection result, and a failure condition. The inspection instrument is an instrument subjected to an inspection by the inspector, and includes the first transformer 11A and the second transformer 11B illustrated in FIG. 1 in the present embodiment. When the inspection instrument is a transformer, the transformer ID is set as the inspection instrument.

The data group “MT1” in the inspection history data 201 illustrated in FIG. 6 indicates that the first transformer 11A (transformer ID: Tr_A) was inspected on Sep. 8, 2010, and the inspection result was determined as failure because rust was found. The data group “MT2” indicates that the second transformer 11B (transformer ID: Tr_B) was inspected on Oct. 9, 2010, and the inspection result was determined as good.

The inspection history data 201 is data inputted to the equipment failure prediction device 3 (refer to FIG. 1) by the inspector. The method of inputting data by the inspector is not limited. For example, data may be inputted to the equipment failure prediction device 3 from a portable terminal held by the inspector at an inspection through the network 2 (refer to FIG. 1). Alternatively, data acquired at an inspection by the inspector may be stored in a portable storage device (memory medium), and the data may be inputted to the equipment failure prediction device 3 through this storage device. Alternatively, the inspector may operate the operation unit 122 (refer to FIG. 1) to input data to the equipment failure prediction device 3.

The inspection history data 201 is not limited to the configuration illustrated in FIG. 6, and may include information on an inspection result as appropriate.

FIG. 7 illustrates an exemplary configuration of the installation environment data.

The installation environment data 202 manages information (environment attribute) on an area (installation area) in which the electrical power distribution equipment managed by the equipment failure prediction system 1 (refer to FIG. 1) is installed. The installation environment data 202 includes items such as salt damage, lightning damage, and wind damage in the present embodiment.

The installation environment data 202 illustrated in FIG. 7 indicates that no salt damage occurs, lightning damage frequently occurs, and strong wind has large influence in Area 1 (refer to FIG. 1), and indicates that salt damage is likely to occur, lightning damage is unlikely to occur, and strong wind has little influence in Area 2 (refer to FIG. 1).

The installation environment data 202 is not limited to the configuration illustrated in FIG. 7, and may include information on an environment attribute affecting the electrical power distribution equipment, as appropriate.

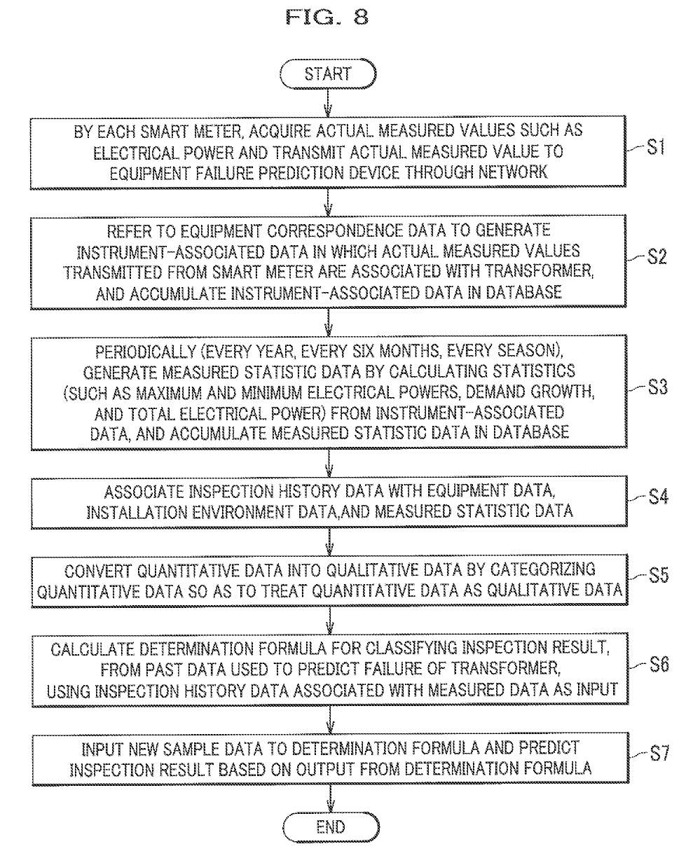

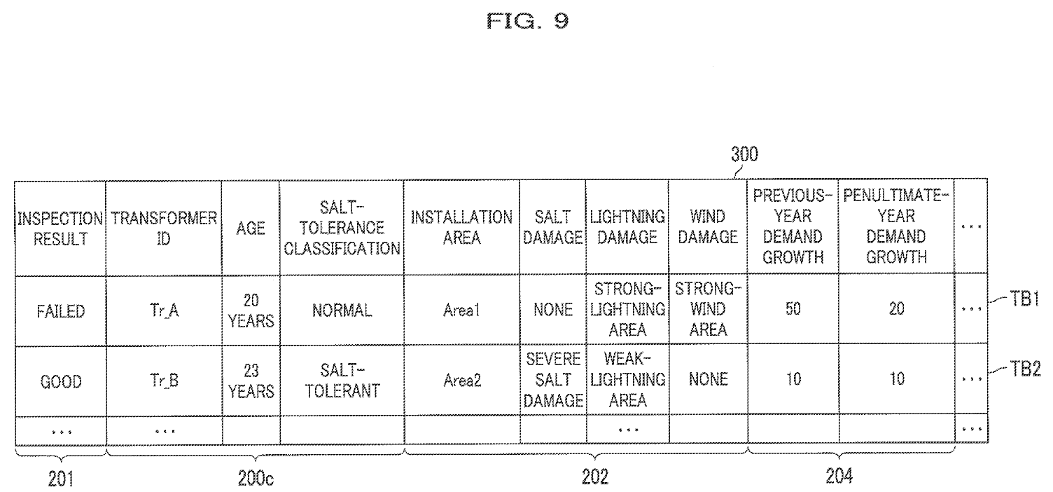

FIG. 8 is a flowchart of a procedure of predicting failure of the equipment by the equipment failure prediction system. FIG. 9 illustrates a prediction data table.

The following describes the procedure of prediction by the equipment failure prediction system 1 (refer to FIG. 1) with reference to the flowchart illustrated in FIG. 8 (refer to FIGS. 1 to 7 as appropriate).

In the procedure illustrated in FIG. 8, a procedure at step S1 is executed by the first smart meter 12A to the fourth smart meter 12D to transmit actual measured values to the equipment failure prediction device 3, and procedures at step S2 or later are performed by the CPU 115 of the equipment failure prediction device 3 executing the failure prediction program 117.

Each smart meter (the first smart meter 12A to the fourth smart meter 12D) measures the electrical power and the like (in the present embodiment, the amount of electrical power, the voltage, and the current) at the corresponding house (the first house Hm1 to the fourth house Hm4) to acquire actual measured values, and transmits the actual measured values to the equipment failure prediction device 3 through the network 2 (step S1). For example, the smart meter transmits the actual measured values to the equipment failure prediction device 3 at a predetermined time interval (for example, at an interval of 30 minutes).

Having received the actual measured values transmitted from the smart meter, the CPU 115 aggregates the actual measured values to produce the smart meter data 203a and accumulates the smart meter data 203a in the database 121. In addition, the CPU 115 associates the actual measured values included in the smart meter data 203a with the corresponding transformer by referring to the equipment correspondence data 200a so as to generate the instrument-associated data 203b and accumulate the instrument-associated data 203b in the database 121 (step S2).

As illustrated in the smart meter data 203a in FIG. 4A, actual measured values (the amount of electrical power, the voltage, and the current, for example) transmitted by each of the first smart meter 12A to the fourth smart meter 12D correspond to a meter ID. The CPU 115 extracts the transformer ID corresponding to the meter ID by referring to the equipment correspondence data 200a so as to associate the actual measured values with the transformer ID. In this processing, the CPU 115 calculates (aggregates) the amount of electrical power, the voltage, and the current of each transformer based on the relevant Equations 1A to 1C and Equations 2A to 2C, and associates the amount of electrical power, the voltage, and the current with the transformer ID so as to generate the instrument-associated data 203b. In this manner, the CPU 115 aggregates actual measured values transmitted from each smart meter, and associates the actual measured values with the corresponding transformer so as to generate the instrument-associated data 203b.

The CPU 115 periodically (every year, every six months, or every season, for example) calculates statistics (the maximum electrical power, the minimum electrical power, the demand growth, the total amount of electrical power) from the instrument-associated data 203b so as to generate the measured statistic data 204, and accumulates the measured statistic data 204 in the database 121 (step S3).

The CPU 115 calculates statistics (the maximum electrical power, the minimum electrical power, the demand growth, the total amount of electrical power) based on actual measured values for each transformer indicated by the instrument-associated data 203b produced at step S2 so as to generate the measured statistic data 204, and accumulates the measured statistic data 204 in the database 121.

The maximum electrical power is the maximum value of electrical power distributed from each transformer in a duration of interest, and the minimum electrical power is the minimum value of electrical power distributed from each transformer in a duration of interest.

The total amount of electrical power is the sum of all values of the amount of electrical power in the instrument-associated data 203b. The demand growth is a difference between the total amount of electrical power in a duration of interest and the total amount of electrical power in the previous duration.

The statistics included in the measured statistic data 204 are not limited to the maximum electrical power, the minimum electrical power, the demand growth, and the total amount of electrical power described above. For example, the statistics may include the average amount of electrical power and a voltage change amount.

The CPU 115 associates the inspection history data 201 with the equipment data 200, the installation environment data 202, and the measured statistic data 204 with one another (step S4). At step S4, the CPU 115 associates the inspection history data 201 with the instrument information data 200c of the equipment data 200, the installation environment data 202, and the measured statistic data 204 using a transformer ID as a key, so as to generate a prediction data table 300 illustrated in FIG. 9.

The prediction data table 300 is generated by coupling the inspection history data 201, the instrument information data 200c of the equipment data 200, the installation environment data 202, and the measured statistic data 204 using a transformer ID as a key. The prediction data table 300 includes data included in an inspection result (the inspection history data 201), a salt-tolerance classification (the instrument information data 200c), an installation area (the installation environment data 202), salt damage, lightning damage, and wind damage (the installation environment data 202). In addition, the prediction data table 300 includes data of an age, a previous-year demand growth, and a penultimate-year demand growth.

The age is calculated by the CPU 115 based on the manufacturing date in the instrument information data 200c. Specifically, the CPU 115 calculates the number of years past since the manufacturing date at the inspection date and time included in the inspection history data 201, and sets a result of the calculation as the age.

The CPU 115 extracts the demand growth of the previous year of the inspection date and time from the demand growth included in the measured statistic data 204, and sets the extracted demand growth as the previous-year demand growth. The CPU 115 also extracts the demand growth of the penultimate year of the inspection date and time from the demand growth included in the measured statistic data 204, and sets the extracted demand growth as the penultimate-year demand growth.

For example, when the inspection date and time is in 2010, the previous-year demand growth is set to the demand growth in 2009, and the penultimate-year demand growth is set to the demand growth in 2008.

In this manner, the CPU 115 generates the prediction data table 300.

A data group “TB1” in the prediction data table 300 illustrated in FIG. 9 is based on the inspection history data 201 of the first transformer 11A, and associates the inspection history data 201, the measured statistic data 204, and the equipment data 200 (instrument information data 200c) with one another using the transformer ID (Tr_A) of the first transformer 11A as a key. The instrument information data 200c is associated with the installation environment data 202 by using an installation area (Area 1) as a key.

In this manner, the inspection history data 201, the instrument information data 200c, the measured statistic data 204, the equipment data 200, and the installation environment data 202 are associated with one another.

A data group “TB2” in the prediction data table 300 illustrated in FIG. 9 is based on the inspection history data 201 of the second transformer 11B, and associates the inspection history data 201, the measured statistic data 204, and the equipment data 200 (instrument information data 200c) with one another using the transformer ID (Tr_B) of the second transformer 11B as a key. The instrument information data 200c is associated with the installation environment data 202 by using an installation area (Area 2) as a key.

In this manner, the inspection history data 201, the equipment data 200 (instrument information data 200c), the measured statistic data 204, and the installation environment data 202 are associated with one another so as to generate the prediction data table 300.

Having produced the prediction data table 300, the CPU 115 converts the quantitative data D2 into qualitative data by categorizing the quantitative data D2 so as to treat the quantitative data D2 as the qualitative data D1 (step S5). In other words, the CPU 115 categorizes the measured statistic data 204 so as to treat the measured statistic data 204, which is the quantitative data D2, as the qualitative data D1.

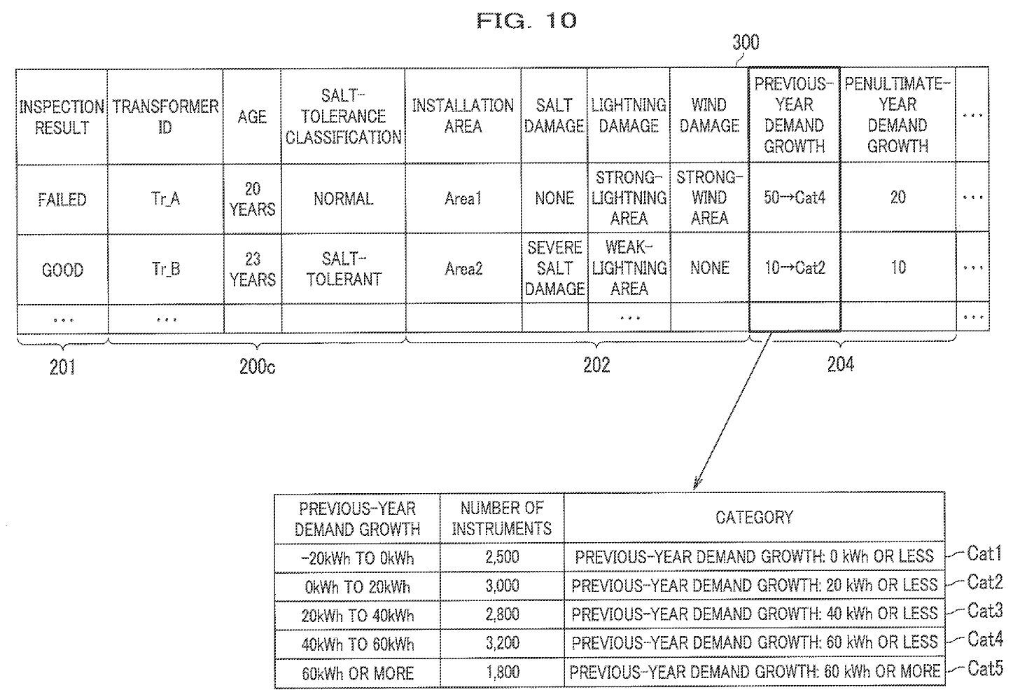

FIG. 10 illustrates an example of categorizing measured statistic data.

FIG. 10 illustrates an example of categorizing the previous-year demand growth of the measured statistic data 204 included in the prediction data table 300.

In the example illustrated in FIG. 10, the numerical value ranges of the previous-year demand growth are set so that the number of instruments (in the present embodiment, the number of transformers) is substantially equal between the numerical value ranges. Each of the set numerical value ranges is one category. The previous-year demand growth (quantitative data D2) is classified into newly set categories, and thus can be treated as the qualitative data D1.

For example, as illustrated in FIG. 10, the CPU 115 classifies the previous-year demand growth having a value in a range of −20 kWh to 0 kWh into the category (Cat1) of “previous-year demand growth: 0 kWh or less”, the previous-year demand growth having a value in a range of 0 kWh to 20 kWh into the category (Cat2) of “previous-year demand growth: 20 kWh or less”, the previous-year demand growth having a value in a range of 20 kWh to 40 kWh into the category (Cat3) of “previous-year demand growth: 40 kWh or less”, the previous-year demand growth having a value in a range of 40 kWh to 60 kWh into the category (Cat4) of “previous-year demand growth: 60 kWh or less”, and the previous-year demand growth having a value in a range of 60 kWh or more into the category (Cat5) of “previous-year demand growth: 60 kWh or more”.

In this manner, the CPU 115 classifies the previous-year demand growth as a statistic into categories each defined by a numerical value range.

In the example illustrated in FIG. 10, since the previous-year demand growth for the first transformer 11A is 50 kWh, the CPU 115 classifies the previous-year demand growth into the category (Cat4) of “previous-year demand growth: 60 kWh or less”. Since the previous-year demand growth for the second transformer 11B is 10 kWh, the CPU 115 classifies the previous-year demand growth into the category (Cat2) of “previous-year demand growth: 20 kWh or less”.

The CPU 115 categorizes the other pieces of the quantitative data D2 such as “age” and “penultimate-year demand growth” by the same method as appropriate.

Having categorized the quantitative data D2, the CPU 115 calculates a determination formula for classifying the inspection result, from past data used to predict failure of each transformer (the first transformer 11A and the second transformer 11B), using the inspection history data 201 associated with actual measured values transmitted from the smart meters 12A to 12D as an input (step S6). In the present embodiment, the inspection result is “failed” or “good”, and thus the CPU 115 calculates a determination formula for classifying occurrence of failure at each transformer at step S6.

Then, the CPU 115 inputs a new sample to the calculated determination formula and predicts the inspection result based on an output from the determination formula (step S7). In the present embodiment, the CPU 115 predicts occurrence of failure at each transformer at step S7.

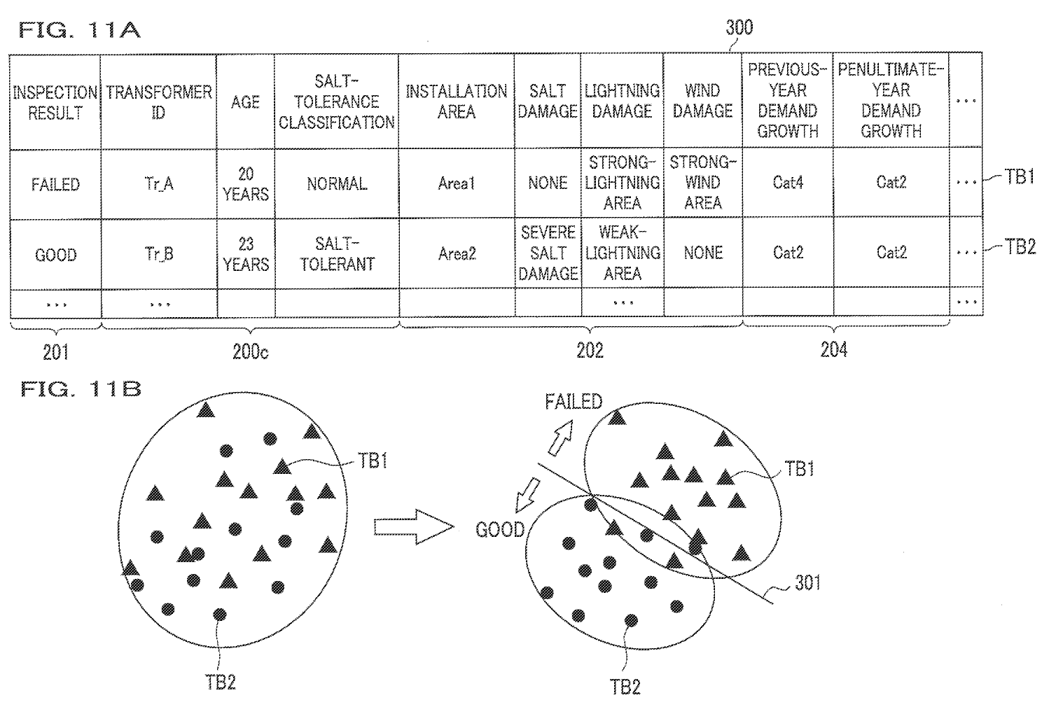

At steps S6 and S7, the CPU 115 predicts occurrence of failure at each transformer using a data group (TB1 and TB2, for example) included in the prediction data table 300 produced at step S4 as an input. In the present embodiment, the CPU 115 predicts occurrence of failure at the transformer by a statistical method called mathematical quantification theory class II. The mathematical quantification theory class II is discriminant analysis on a category variable, and is a method for obtaining, when it is clear that a previously given data group is divided into different groups, a criterion (determination formula) used to determine which group a newly obtained data group (sample data) is classified into. Since this method is generally used, its detailed description will be omitted. The following describes an outline of applying the mathematical quantification theory class II to the present embodiment with reference to FIGS. 11A and 11B to FIGS. 13A and 13B.

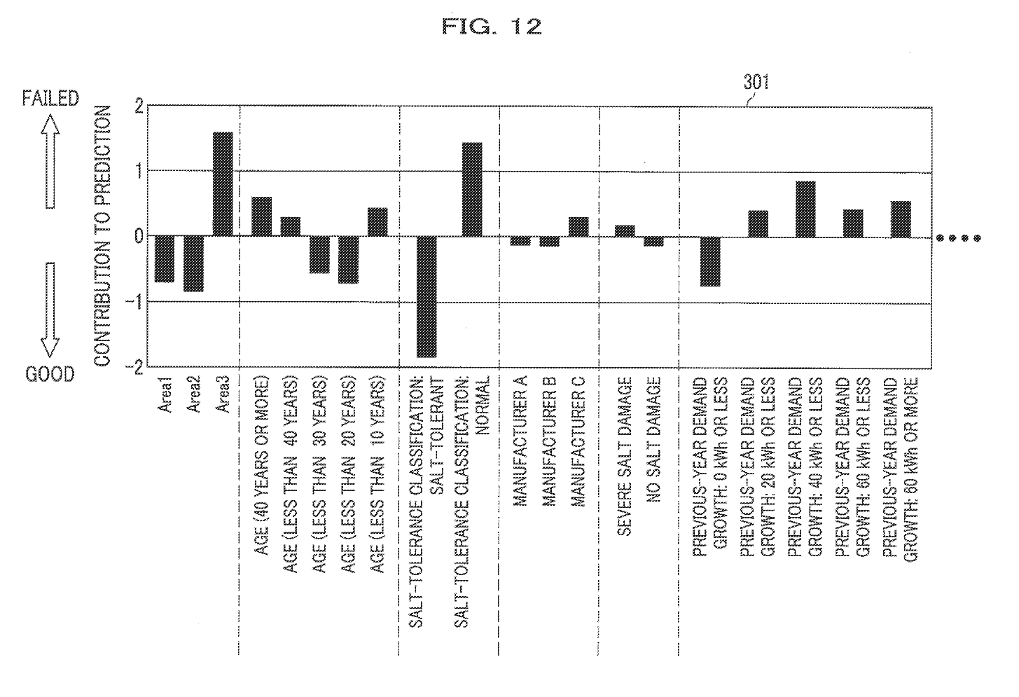

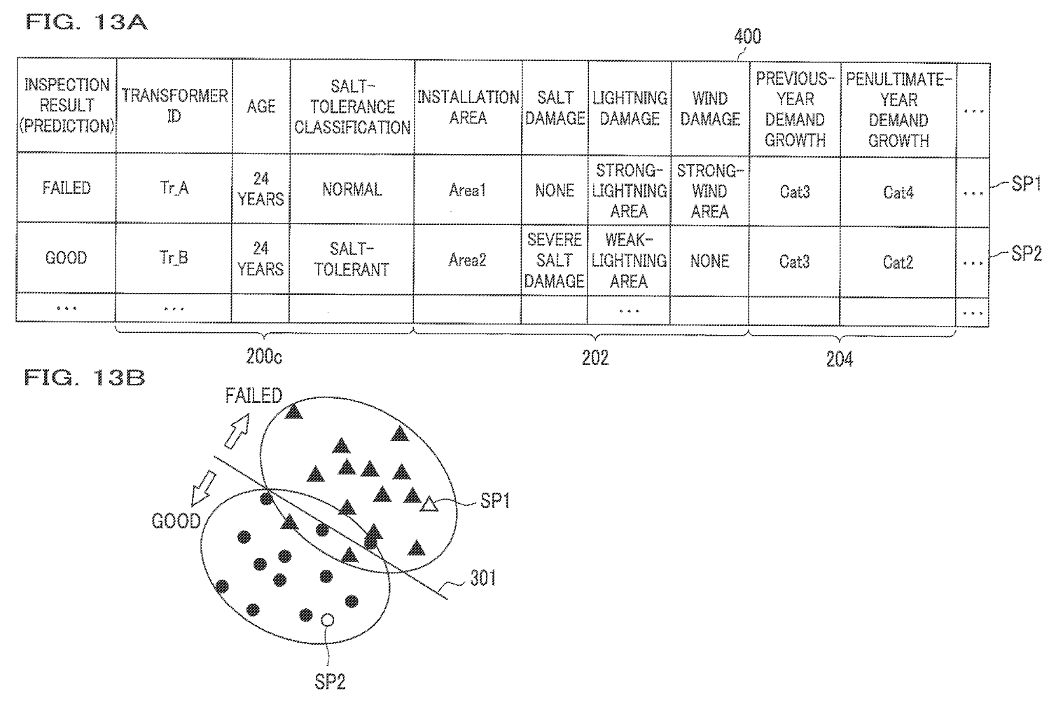

FIGS. 11A and 11B are each a pattern diagram illustrating the outline of applying the mathematical quantification theory class II to the present embodiment. FIG. 11A illustrates a prediction data table, and FIG. 11B is a schematic diagram illustrating distribution of data groups. FIG. 12 illustrates the determination formula. FIG. 13A illustrates sample data used to predict the inspection result, and FIG. 13B illustrates a result of determination using the determination formula.

The CPU 115 sets, as prediction data, data included in each data group included in the prediction data table 300 produced at step S4.

As illustrated in FIG. 11A, the prediction data table 300 according to the present embodiment is categorized into “good” or “failed” depending on the inspection result. As illustrated by an image on a left side in FIG. 11B, data groups associated with the inspection results of “good” and “failed” are distributed. In FIG. 11B, a data group having the inspection result of “good” is illustrated as a black circle, and a data group having the inspection result of “failed” is illustrated as a black triangle. For example, the data group “TB1” is represented by a black triangle, and the data group “TB2” is represented by a black circle.

The CPU 115 calculates a determination formula 301 based on the mathematical quantification theory class II so that each data group included in the prediction data table 300 is categorized based on the inspection result of “good” or “failed”.

The CPU 115 weights prediction data (data included in a data group) by multiplying the prediction data by each predetermined coefficient determined by the determination formula 301 set based on the mathematical quantification theory class II. In the weighting, the CPU 115 determines each weight (coefficient) of the prediction data such that each data group included in the prediction data table 300 is categorized based on the inspection result of “good” or “failed”. The coefficient of the prediction data is set based on a result of a statistical analysis on records of inspections in the past to find which condition and state an instrument determined to be “failed” is in, whereby the determination formula 301 as a determination criterion is obtained.

As illustrated in FIG. 12, for example, the CPU 115 determines the coefficient of prediction data included in the prediction data table 300 so as to calculate the determination formula 301.

A positive value of an exemplary coefficient of the determination formula 301 illustrated in FIG. 12 indicates that the determination of “failed” is likely to be made, and a negative value thereof indicates that the determination of “good” is likely to be made. A larger positive value indicates that the determination of “failed” is more likely to be made, and a larger negative value indicates that the determination of “good” is likely to be made.

In the right diagram of FIG. 11B, data groups (black triangles) determined to be “failed” exist in a range in which the determination formula 301 indicates “good”. In addition, data groups (black circles) determined to be “good” exist in a range in which the determination formula 301 indicates “failed”. This illustrates that the accuracy of classification of a data group into “good” or “failed” by the determination formula 301 is not 100%.

When sample data 400 as illustrated in FIG. 13A is inputted, the CPU 115 predicts the inspection result based on the inputted sample data 400. The CPU 115 according to the present embodiment predicts occurrence of failure at the first transformer 11A and the second transformer 11B (refer to FIG. 1).

The inputted sample data 400 preferably includes data included in the prediction data table 300 illustrated in FIG. 10.

For example, a data group “SP1” of the sample data 400 illustrated in FIG. 13A is a group of sample data for predicting the inspection result of the first transformer 11A (refer to FIG. 1).

In order to predict the inspection result of the first transformer 11A (refer to FIG. 1), the inspector inputs the transformer ID (Tr_A) of the first transformer 11A to the equipment failure prediction device 3.

The CPU 115 extracts the manufacturing date of the first transformer 11A from the instrument information data 200c (refer to FIG. 3C) and calculates the current age (24 years in the example illustrated in FIG. 13A). The CPU 115 also extracts information such as the salt-tolerance classification (normal), the installation area (Area 1), and the manufacturer (manufacturer A) of the first transformer 11A from the instrument information data 200c. The CPU 115 also extracts salt damage (none), lightning damage (strong-lightning area), and wind damage (strong-wind area) for the installation area (Area 1) of the first transformer 11A from the installation environment data 202 (refer to FIG. 7). In addition, the CPU 115 calculates the previous-year demand growth and the penultimate-year demand growth of the first transformer 11A from the measured statistic data 204 (refer to FIG. 5). The previous-year demand growth is calculated based on data of the previous year of the present time. Similarly, the penultimate-year demand growth is calculated based on data of the penultimate year of the present time.

In this manner, the CPU 115 generates sample data based on an inputted transformer ID by referring to the database 121 (refer to FIG. 2) as needed. For example, as illustrated with the sample data 400 in FIG. 13A, a data group SP1 corresponding to the first transformer 11A (transformer ID: Tr_A) is generated.

When the transformer ID (Tr_B) of the second transformer 11B (refer to FIG. 1) is inputted, the CPU 115 generates a data group SP2 of the sample data 400 corresponding to the second transformer 11B in a similar manner.

The CPU 115 weights data of the generated data groups SP1 and SP2 of the sample data 400 with the coefficients set to the determination formula 301 illustrated in FIG. 12. As a result, when the data group SP1 is in an area of “failed” with respect to the determination formula 301 as illustrated with a white triangle in FIG. 13B, the CPU 115 predicts the inspection result of the first transformer 11A (refer to FIG. 1) to be “failed”. In other words, the CPU 115 predicts occurrence of failure at the first transformer 11A.

When the data group SP2 is in an area of “good” with respect to the determination formula 301 as illustrated with a white circle in FIG. 13B, the CPU 115 predicts the inspection result of the second transformer 11B (refer to FIG. 1) to be “good”. In other words, the CPU 115 predicts no occurrence of failure at the second transformer 11B.

As illustrated in FIG. 8, the equipment failure prediction device 3 (CPU 115) according to the present embodiment executes the procedures at steps S2 to S7 based on actual measured values received from the first smart meter 12A to the fourth smart meter 12D at step S1 so as to predict the inspection results (occurrence of failure) of the first transformer 11A and the second transformer 11B. In the prediction of the inspection results, the CPU 115 uses the method of the mathematical quantification theory class II.

For example, the inspector recognizes the first transformer 11A (refer to FIG. 1) for which the inspection result is predicted as “failed”, as equipment predicted to generate failure, and increases the frequency of inspection. The inspector recognizes the second transformer 11B (refer to FIG. 1) for which the inspection result is predicted as “good”, as equipment predicted not to generate failure, and postpones or cancels an inspection (or reduces an inspection load). In this manner, the inspector can plan the inspection. This achieves an efficient inspection as compared to the case where all transformers are inspected.

As described above, the equipment failure prediction device 3 (CPU 115) according to the present embodiment illustrated in FIG. 1 predicts the inspection results (occurrence of failure) of the first transformer 11A and the second transformer 11B based on the sample data 400 (refer to FIG. 13A). The sample data 400 includes the measured statistic data 204 (statistic) as the quantitative data D2 (refer to FIG. 2). In addition, the sample data 400 includes the installation environment data 202 and the instrument information data 200c as the qualitative data D1 (refer to FIG. 2). Moreover, the determination formula 301 (refer to FIG. 12) is set based on a result of a statistical analysis on the records (in other words, the inspection history data 201 illustrated in FIG. 6) of inspections in the past.

Thus, the CPU 115 can predict the inspection results (occurrence of failure) of the first transformer 11A and the second transformer 11B by using the measured statistic data 204 (statistics), the inspection history data 201, the instrument information data 200c, and the installation environment data 202.

In addition, the CPU 115 weights the instrument information data 200c (refer to FIG. 2) and the installation environment data 202 (refer to FIG. 2) by using the determination formula 301 (refer to FIG. 12), and predicts the inspection results (occurrence of failure) of the first transformer 11A and the second transformer 11B based on the weighted data. In the present embodiment, as in the example illustrated in FIG. 12, the CPU 115 weights the age and the salt-tolerance classification included in the instrument information data 200c. In addition, the CPU 115 weights the installation area, the age, and the salt damage included in the installation environment data 202.

Then, the CPU 115 categorizes data into “good” and “failed” by using the determination formula 301 based on the weighting results as illustrated in FIG. 13B, and predicts occurrence of failure at a transformer (the first transformer 11A in the example illustrated in FIG. 13A) corresponding to a data group (the data group “SP1” in the example illustrated in FIG. 13B) categorized as “failed”.

The CPU 115 classifies the measured statistic data 204 (statistics) as the quantitative data D2 into categories each defined by a numerical value range at step S5 illustrated in FIG. 8, and then weights these categories by using the determination formula 301 (refer to FIG. 12). Then, the CPU 115 categorizes the data into “good” and “failed” by using the determination formula 301 as illustrated in FIG. 13B based on the weighted instrument information data 200c, the weighted installation environment data 202, and the weighted categories into which the measured statistic data 204 are classified, and predicts occurrence of failure at a transformer (the first transformer 11A in the example illustrated in FIG. 13A) corresponding to a data group (the data group “SP1” in the example illustrated in FIG. 13B) categorized as “failed”.

In this manner, the equipment failure prediction device 3 (CPU 115) according to the present embodiment illustrated in FIG. 1 predicts an inspection result (occurrence of failure) at each transformer (the first transformer 11A and the second transformer 11B) by using statistics (the measured statistic data 204 illustrated in FIG. 5) calculated from actual measured values transmitted from the corresponding smart meter (the first smart meter 12A to the fourth smart meter 12D).

In addition, the CPU 115 aggregates actual measured values transmitted from each smart meter and associates the actual measured values with the corresponding transformer to calculate statistics.

Moreover, the CPU 115 predicts an inspection result (occurrence of failure) at a transformer by using the inspection history data 201 (refer to FIG. 2), the instrument information data 200c (refer to FIG. 3C), and the installation environment data 202 (refer to FIG. 2) accumulated as the qualitative data D1 (refer to FIG. 2) in the database 121.

As described above, the equipment failure prediction device 3 (CPU 115) according to the present embodiment classifies the measured statistic data 204 (refer to FIG. 2) as the quantitative data D2 into categories each defined by a numerical value range and weights these categories so as to treat the quantitative data D2 as the qualitative data D1 (refer to FIG. 2). Accordingly, the CPU 115 can predict the inspection result (occurrence of failure) of a transformer (the first transformer 11A and the second transformer 11B) by using the measured statistic data 204 as the quantitative data D2, and the inspection history data 201 (refer to FIG. 2), the instrument information data 200c (refer to FIG. 3C), and the installation environment data 202 (refer to FIG. 2) as the qualitative data D1. In the prediction, the equipment failure prediction device 3 may use the method of the mathematical quantification theory class II. In this manner, the inspection result of the transformer can be predicted based on information (the amount of electrical power, the voltage, and the current in the present embodiment) indicating the internal state of the transformer, thereby achieving a highly accurate prediction.

Data acquired at inspections of the first transformer 11A and the second transformer 11B by the inspector is inputted to the inspection history data 201 (refer to FIG. 2) and accumulated in the database 121 (refer to FIG. 2). Thus, unique data (information) on a transformer (such as the first transformer 11A) provided with an inspection is accumulated. This leads to an increased amount of data used to predict an inspection result, thereby achieving a highly accurate prediction.

The present invention is not limited to the embodiments described above. For example, the embodiments are described in detail for facilitating the understanding of the present invention, and thus the present invention is not necessarily limited to the whole described configuration.

Part of the configuration of an embodiment may be replaced with the configuration of another embodiment. Alternatively, the configuration of an embodiment may be added to the configuration of another embodiment.

In addition, the present invention is not limited to the embodiments described above, and may be modified as appropriate without departing from the gist of the invention.

For example, in the present embodiment, the prediction of an inspection result is performed for the first transformer 11A and the second transformer 11B illustrated in FIG. 1, but is not limited to transformers. For example, the first smart meter 12A to the fourth smart meter 12D may be inspected.

It is a matter of course that the number of transformers for which an inspection result is predicted by the equipment failure prediction device 3 (CPU 115) is not limited to two, and the equipment failure prediction device 3 (CPU 115) may predict the inspection results of three transformers or more. In addition, the number of houses (the first house Hm1 to the fourth house Hm4) to which power is distributed by one transformer is not limited to two. One transformer may distribute electrical power to three houses or more. In this case, a smart meter is preferably installed at each house.

In the present embodiment, at generation of the sample data 400 illustrated in FIG. 13A, when the inspector inputs a transformer ID to the equipment failure prediction device 3 (refer to FIG. 1), the equipment failure prediction device 3 generates the sample data 400. The present invention is not limited to this configuration, and the equipment failure prediction device 3 (CPU 115) may automatically generate the sample data 400 at a predetermined time interval (for example, a time interval such as two years by which an inspection is needed), and may predict the inspection results of the first transformer 11A (refer to FIG. 1) and the second transformer 11B (refer to FIG. 1) based on the generated sample data 400.

In this case, it is possible to instantly notify the inspector of a transformer in need of an inspection by, for example, transmitting the transformer ID of a transformer for which the inspection result is predicted as “failed” to a handy terminal held by the inspector.

The equipment failure prediction device 3 (CPU 115) according to the present embodiment predicts the inspection result of a transformer by using the inspection history data 201 (refer to FIG. 2), the instrument information data 200c (refer to FIG. 3C), the installation environment data 202 (refer to FIG. 2), and the measured statistic data 204 (refer to FIG. 2). The present invention is not limited to this configuration, and the equipment failure prediction device 3 (CPU 115) may predict the inspection result of a transformer by using, for example, the measured statistic data 204 only. Alternatively, the equipment failure prediction device 3 (CPU 115) may predict the inspection result of a transformer by using, for example, the measured statistic data 204 and the inspection history data 201.

In the present embodiment, as illustrated in FIG. 1, the database 121 (data storage device 121a) is provided to the equipment failure prediction device 3. The present invention is not limited to this configuration, and the data storage device 121a may be arranged separately from the equipment failure prediction device 3. In this case, the equipment failure prediction device 3 and the data storage device 121a only need to be connected through the network 2, for example.

The present embodiment exemplarily describes an inspection service of power poles in the electrical power distribution equipment, but the application range of the present invention is not limited to this field and object.

### DESCRIPTION OF REFERENCE SIGNS

1: equipment failure prediction system; 2: network; 3: equipment failure prediction device; 11A: first transformer (inspection target equipment); 11B: second transformer (inspection target equipment); 12A: first smart meter (terminal device); 12B: second smart meter (terminal device); 12C: third smart meter (terminal device); 12D: fourth smart meter (terminal device); 115: CPU (control unit); 118: network interface (interface unit); 121: database; 121a: data storage device; 200c: the instrument information data; 201: the inspection history data; 202: installation environment data; 204: measured statistic data (statistic); 301: determination formula; D1: qualitative data; D2: quantitative data

1. An equipment failure prediction system comprising:
an equipment failure prediction device connectable to a network;
a data storage device storing a database therein; and
a plurality of terminal devices connectable to the network, wherein
each of the terminal devices transmits quantitative data to the equipment failure prediction device through the network, the quantitative data obtained by quantifying information provided by inspection target equipment, and
the equipment failure prediction device accumulates the transmitted quantitative data in the database, and predicts occurrence of failure at the inspection target equipment by using a statistic calculated from the quantitative data accumulated in the database.

2. The equipment failure prediction system according to claim 1, wherein the equipment failure prediction device:
aggregates the quantitative data transmitted from the terminal devices and associates the aggregated quantitative data with the inspection target equipment, and
calculates the statistic from the quantitative data associated with the inspection target equipment.

3. The equipment failure prediction system according to claim 1, wherein the equipment failure prediction device:
retains, as qualitative data, inspection history data obtained by inspecting the inspection target equipment, and
predicts the occurrence of failure at the inspection target equipment by using the inspection history data in addition to the statistic.

4. The equipment failure prediction system according to claim 3, wherein the equipment failure prediction device:
retains, as qualitative data, instrument information data including information on the inspection target equipment, and installation environment data including environment information on environment in which the inspection target equipment is installed, and
predicts the occurrence of failure at the inspection target equipment by using the instrument information data and the installation environment data in addition to the statistic and the inspection history data.

5. The equipment failure prediction system according to claim 2, wherein the equipment failure prediction device:
classifies the statistic calculated from the quantitative data associated with the inspection target equipment into categories each defined by a numerical value range of the statistic, and
predicts the occurrence of failure at the inspection target equipment based on the categories.

6. The equipment failure prediction system according to claim 4, wherein the equipment failure prediction device:
classifies the statistic calculated from the quantitative data associated with the inspection target equipment into categories each defined by a numerical value range of the statistic,
weights the categories, the instrument information data, and the installation environment data by using a determination formula based on mathematical quantification theory class II, and
predicts the occurrence of failure at the inspection target equipment based on the weighed categories, the weighed instrument information data, and the weighed installation environment data.

7. An equipment failure prediction device comprising:
an interface unit used to connect to a network;
a data storage device storing database therein; and
a control unit, and
wherein
the equipment failure prediction device is connected through the network to a plurality of terminal devices which are provided with information from inspection target equipment and generate quantitative data by quantifying the provided information, and
the control unit:
accumulates the quantitative data transmitted from the terminal devices in the database, and calculates a statistic from the quantitative data accumulated in the database, and
predicts occurrence of failure at the inspection target equipment by using the calculated statistic.

8. The equipment failure prediction device according to claim 7, wherein the control unit:
aggregates the quantitative data transmitted from the terminal devices and associates the aggregated quantitative data with the inspection target equipment, and
calculates the statistic from the quantitative data associated with the inspection target equipment.

9. The equipment failure prediction device according to claim 7, wherein:
inspection history data obtained by inspecting the inspection target equipment is accumulated as qualitative data in the database, and
the control unit predicts the occurrence of failure at the inspection target equipment by using the inspection history data in addition to the statistic.

10. The equipment failure prediction device according to claim 9, wherein:
instrument information data including information on the inspection target equipment, and installation environment data including environment information on environment in which the inspection target equipment is installed are accumulated as qualitative data in the database, and
the control unit predicts the occurrence of failure at the inspection target equipment by using the instrument information data and the installation environment data in addition to the statistic and the inspection history data.

11. The equipment failure prediction device according to claim 8, wherein the control unit:
classifies the statistic calculated from the quantitative data associated with the inspection target equipment into categories each defined by a numerical value range of the statistic, and
predicts the occurrence of failure at the inspection target equipment based on the categories.

12. The equipment failure prediction device according to claim 10, wherein the control unit:
classifies the statistic calculated from the quantitative data associated with the inspection target equipment into categories each defined by a numerical value range of the statistic,
weights the categories, the instrument information data, and the installation environment data by using a determination formula based on mathematical quantification theory class II, and
predicts the occurrence of failure at the inspection target equipment based on the weighted category, the weighted instrument information data, and the weighted installation environment data.

13. An equipment failure prediction method executed by a control unit of an equipment failure prediction device including:
an interface unit used to connect to a network; and
a data storage device storing a database therein, and
the equipment failure prediction device being connected through the network to a plurality of terminal devices which are provided with information by inspection target equipment and which generate quantitative data by quantifying the provided information, the method comprising:
accumulating the quantitative data transmitted from each of the terminal devices in the database;
aggregating the quantitative data accumulated in the database and associating the aggregated quantitative data with the inspection target equipment;
calculating a statistic from the quantitative data associated with the inspection target equipment;
classifying the calculated statistic into categories each defined by a numerical value range of the statistic;
weighting the categories by using a determination formula based on mathematical quantification theory class II; and
predicting occurrence of failure at the inspection target equipment based on the weighted categories.

14. The equipment failure prediction method according to claim 13, further comprising:
weighting instrument information data accumulated in the database and including information on the inspection target equipment by using the determination formula based on the mathematical quantification theory class II; and
weighting installation environment data accumulated in the database and including environment information on environment in which the inspection target equipment is installed, by using the determination formula based on the mathematical quantification theory class II,
wherein the control unit predicts the occurrence of failure at the inspection target equipment based on the weighted instrument information data and the weighted installation environment data in addition to the weighted categories.

15. The equipment failure prediction system according to claim 2, wherein the equipment failure prediction device:
retains, as qualitative data, inspection history data obtained by inspecting the inspection target equipment, and
predicts the occurrence of failure at the inspection target equipment by using the inspection history data in addition to the statistic.

16. The equipment failure prediction system according to claim 3, wherein the equipment failure prediction device:
classifies the statistic calculated from the quantitative data associated with the inspection target equipment into categories each defined by a numerical value range of the statistic, and
predicts the occurrence of failure at the inspection target equipment based on the categories.

17. The equipment failure prediction system according to claim 4, wherein the equipment failure prediction device:
classifies the statistic calculated from the quantitative data associated with the inspection target equipment into categories each defined by a numerical value range of the statistic, and
predicts the occurrence of failure at the inspection target equipment based on the categories.

18. The equipment failure prediction device according to claim 8, wherein:
inspection history data obtained by inspecting the inspection target equipment is accumulated as qualitative data in the database, and
the control unit predicts the occurrence of failure at the inspection target equipment by using the inspection history data in addition to the statistic.

19. The equipment failure prediction device according to claim 9, wherein the control unit:
classifies the statistic calculated from the quantitative data associated with the inspection target equipment into categories each defined by a numerical value range of the statistic, and
predicts the occurrence of failure at the inspection target equipment based on the categories.

20. The equipment failure prediction device according to claim 10, wherein the control unit:
classifies the statistic calculated from the quantitative data associated with the inspection target equipment into categories each defined by a numerical value range of the statistic, and
predicts the occurrence of failure at the inspection target equipment based on the categories.
